(19) United States
(12) Patent Application Publication
(10) Pub. No.: US 2024/0282782 A1
(43) Pub. Date: Aug. 22, 2024

(54) DISPLAY PANEL AND DISPLAY DEVICE

(71) Applicant: BOE Technology Group Co., Ltd., Beijing (CN)

(72) Inventors: Guoteng LI, Beijing (CN); Shuilang DONG, Beijing (CN); Xinhong LU, Beijing (CN); Jingshang ZHOU, Beijing (CN); Liuqing LI, Beijing (CN); Zhao CUI, Beijing (CN); Dapeng XUE, Beijing (CN); Zhiqiang XU, Beijing (CN); Jintao PENG, Beijing (CN); Weixing LIU, Beijing (CN); Kai GUO, Beijing (CN); Chunfang ZHANG, Beijing (CN); Meirong LU, Beijing (CN); Wanpeng TENG, Beijing (CN)

(73) Assignee: BOE Technology Group Co., Ltd., Beijing (CN)

(21) Appl. No.: 18/640,015

(22) Filed: Apr. 19, 2024

Related U.S. Application Data
(63) Continuation of application No. PCT/CN2023/077480, filed on Feb. 21, 2023.

(51) Int. Cl. H01L 27/12; H01L 25/16

(52) U.S. Cl. CPC H01L 27/1248; H01L 25/167

(57) ABSTRACT

A display panel and a display device are provided. The display panel includes a plurality of display units, each display unit includes a transparent area, and the display panel further includes a base substrate and a composite functional layer. The composite functional layer is provided on a side of the base substrate and has a first through-hole formed therein, and the first through-hole is provided in the transparent area. The composite functional layer includes a composite transparent layer and a light-shielding layer. The composite transparent layer includes a plurality of transparent functional layers, and includes a light-transmitting part surrounding the first through-hole. An orthographic projection of the light-shielding layer on the base substrate covers an orthographic projection of at least a portion of the light-transmitting part on the base substrate.

### CROSS-REFERENCE TO RELATED APPLICATION

The present application is a continuation of International Application No. PCT/CN2023/077480, filed on Feb. 21, 2023, the entire disclosure of which is hereby incorporated by reference.

### TECHNICAL FIELD

The present disclosure relates to the field of display technology, and specifically, to a display panel and a display device.

### BACKGROUND

In the related art, a display panel may include a plurality of display units, and each display unit may include at least one transparent area and a pixel area provided outside the transparent area. Pixel driving circuits, light-emitting units, and wirings in the display panel are integrated in the pixel area. Since the transparent area is provided, the display panel may allow a viewer to see a background image on the back of the display panel through the display panel while displaying an image.

It is to be noted that the information disclosed in the above background section is only used to enhance the understanding of the background of the present disclosure, and thus may include information that does not constitute the prior art known to those skilled in the art.

### SUMMARY

One aspect of the present disclosure provides a display panel. The display panel includes a plurality of display units, each of the plurality of display units includes a transparent area, and the display panel further includes: a base substrate; and a composite functional layer, provided on a side of the base substrate and having a first through-hole formed therein, the first through-hole being provided in the transparent area. The composite functional layer includes: a composite transparent layer, including a plurality of transparent functional layers, and including a light-transmitting part surrounding the first through-hole; and a light-shielding layer, an orthographic projection of the light-shielding layer on the base substrate covering an orthographic projection of at least a portion of the light-transmitting part on the base substrate.

In an embodiment of the present disclosure, the display panel further includes a light-emitting unit, and the composite functional layer further includes: a second source-drain layer, provided on the side of the base substrate, and including and electrode part connecting to the light-emitting unit; and a second planarization layer, provided on a side of the second source-drain layer away from the base substrate, wherein the light-shielding layer is provided on a side of the second planarization layer away from the base substrate.

In an embodiment of the present disclosure, the display panel further includes a light-emitting unit, and the composite functional layer further includes: a first source-drain layer, provided on the side of the base substrate, a portion of the first source-drain layer being configured to form a data line; a second source-drain layer, provided on a side of the first source-drain layer away from the base substrate, and including an electrode part connecting to the light-emitting unit; and a first planarization layer, provided between the first source-drain layer and the second source-drain layer, a color of the first planarization layer being black and the first planarization layer forming the light-shielding layer.

In an embodiment of the present disclosure, the display panel further includes a light-emitting unit, and the composite functional layer includes any film layers provided between the light-emitting unit and the base substrate; the composite transparent layer includes any film layers provided between the light-emitting unit and the base substrate; and the light-shielding layer includes at least one of a buffer layer, an insulating layer, a passivation layer, a planarization layer, and a conductive layer provided between the light-emitting unit and the base substrate.

In an embodiment of the present disclosure, the light-shielding layer is provided on a side of the composite transparent layer away from the base substrate, and at least a portion of a sidewall of the first through-hole is formed by the light-shielding layer; or the light-shielding layer is provided between the transparent functional layers, and the sidewall of the first through-hole is formed by the transparent functional layer.

In an embodiment of the present disclosure, the light-shielding layer is provided on a side of the composite transparent layer away from the base substrate, a second through-hole is formed in the composite transparent layer, the first through-hole is provided in the second through-hole, and the light-shielding layer covers a sidewall of the second through-hole to form the first through-hole; and an inner diameter of the second through-hole at a location close to the base substrate is smaller than an inner diameter of the second through-hole at a location far from the base substrate.

In an embodiment of the present disclosure, an angle between the sidewall of the second through-hole and the base substrate is greater than or equal to 70° and less than or equal to 75°.

In an embodiment of the present disclosure, the second through-hole includes a first opening far from the base substrate, and the light-transmitting part includes a first light-transmitting part; an orthographic projection of the first light-transmitting part on the base substrate surrounds an orthographic projection of the first opening on the base substrate; and the light-shielding layer includes a first light-shielding part, an orthographic projection of the first light-shielding part on the base substrate covers an orthographic projection of at least a portion of the first light-transmitting part on the base substrate.

In an embodiment of the present disclosure, the composite functional layer further includes: a first source-drain layer, provided between the base substrate and the second source-drain layer, a portion of the first source-drain layer being configured to form a data line; and a first planarization layer, provided between the first source-drain layer and the second source-drain layer, wherein the first planarization layer and the second planarization layer are provided in an area outside the light-transmitting part.

In an embodiment of the present disclosure, the display panel further includes a pixel driving circuit, and the display unit further includes a pixel area integrated with the pixel driving circuit; and the light-shielding layer further includes a third light-shielding part, and the third light-shielding part is provided in the pixel area.

In an embodiment of the present disclosure, a material of the light-shielding layer includes acrylic resin and carbon black particles.

In an embodiment of the present disclosure, the light-shielding layer is formed of a mixture of acetate-1-methoxy-2-acrylic acid, acrylic polymer, and organic dye.

In an embodiment of the present disclosure, the display panel is a Mini LED display panel or a Micro LED display panel.

One aspect of the present disclosure provides a display device including the display panel described above.

It is to be understood that the above general description and the following detailed descriptions are exemplary and explanatory only and do not limit the embodiments of the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principle of the present disclosure. Obviously, the accompanying drawings in the following description are only some of the embodiments of the present disclosure, and a person skilled in the art may obtain other accompanying drawings from these drawings without creative work.

FIG. 1 is a schematic diagram of a structure of a display panel in the related art;

FIG. 2 is a sectional view of the display panel shown in FIG. 1 taken along AA′;

FIG. 3 is a schematic view of a structure of a display panel in the present disclosure;

FIG. 4a is a sectional view of the display panel shown in FIG. 3 taken along BB′;

FIG. 4b is a schematic view of a structure of a display panel in another embodiment of the present disclosure;

FIGS. 5 to 7 are a flow diagram of a process for forming a light-shielding layer of a display panel in an embodiment of the present disclosure;

FIG. 8 is a schematic diagram of a structure of a display panel in another embodiment of the present disclosure;

FIG. 9 is a schematic diagram of a structure of a display panel in another embodiment of the present disclosure;

FIG. 10 is a schematic diagram of a structure of a display panel in another embodiment of the present disclosure.

### DETAILED DESCRIPTION

Example embodiments will now be described more fully with reference to the accompanying drawings. However, the example embodiments may be implemented in a variety of forms and should not be construed as being limited to the examples set forth herein; rather, these embodiments are provided so that the present disclosure may be more comprehensive and complete and the concept of the example embodiments may be conveyed to a person skilled in the art in a comprehensive manner. The same reference numerals in the drawings indicates the same or similar structure, and thus detailed descriptions thereof may be omitted.

The terms “a”, “an”, “said” are used to indicate the presence of one or more elements/components/etc.; and the terms “including” and “having” are used to indicate open-ended inclusion and mean that there may be additional elements/components/etc. in addition to those listed.

FIG. 1 is a schematic diagram of a structure of a display panel in the related art, and as shown in FIG. 1, the display panel may include a plurality of display units Pix, each display unit Pix may include at least one transparent area A1 and a pixel area A2 provided outside the transparent area A1. Pixel driving circuits, light-emitting units, and wirings in the display panel are integrated in the pixel area A2. Since the transparent area A1 is provided, the display panel may allow a viewer to see a background image on the back of the display panel through the display panel while displaying an image.

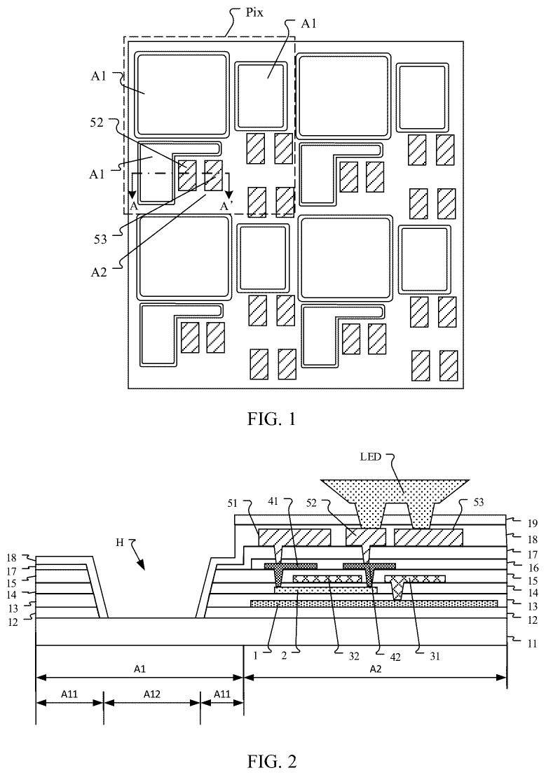

FIG. 2 is a sectional view of the display panel shown in FIG. 1 taken along AA′, and as shown in FIG. 2, the display panel may include a base substrate 11, a first buffer layer 12, a bottom gate layer, a second buffer layer 13, an active layer, an insulating layer 14, a first gate layer, a dielectric layer 15, a first source-drain layer, a first planarization layer 16, a first passivation layer 17, a second source-drain layer, a second source-drain layer, a second passivation layer 18, and a second planarization layer 19 sequentially stacked. The bottom gate layer may be used to form a structure such as a capacitor electrode in a pixel driving circuit, and the bottom gate layer may include a conductive part 1. The active layer is mainly used to form a channel area of a transistor in the pixel driving circuit, for example, the active layer may include an active part 2, and the active part 2 may be used to form a channel area of a transistor. The first gate layer is mainly used to form a gate electrode of a transistor in the pixel driving circuit, for example, the first gate layer may include a conductive part 31 and a conductive part 32, the conductive part 31 may be used to form the gate electrode of the transistor, and the conductive part 32 is a connection part. The first source-drain layer is mainly used to form an interconnection part for connecting conductive structures in different conductive layers, for example, the first source-drain layer may include a conductive part 41 and a conductive part 42, and the first source-drain layer may also be used to form a signal line such as a data line. The second source-drain layer is mainly used to form an electrode part for connecting to the light-emitting unit LED, for example, the second source-drain layer may include a conductive part 51, an electrode part 52 and an electrode part 53, and the electrode part 52 and the electrode part 53 are used to connect to a cathode and anode of the light-emitting unit LED. In the related art, a through-hole H is usually provided in the transparent area A1 to increase a light transmittance of the transparent area A1. Since the through-hole H has a height, when the through-hole H is formed by an etching process, an inner diameter of the through-hole H at an end thereof facing towards the base substrate 11 is smaller than an inner diameter of the through-hole H at an end thereof far from the base substrate 11. At the same time, a transparent film layer with a certain size needs to be provided between the pixel area A2 and the through-hole H, and thus the transparent area A1 may include a through-hole area A12 and a material transparent area A11.

However, diffraction may occur when light from the back of the display panel passes through the transparent area A1. At the same time, since the through-hole area A12 and the material transparent area A11 have different refractive indexes, the light passing through the through-hole area A12 and that passing through the material transparent area A11 may generate a phase difference, which results in a decrease in the intensity of the light in the center of the transparent area A1 and an increase in the brightness of the diffraction spot, thereby resulting in a blurred display of the display panel.

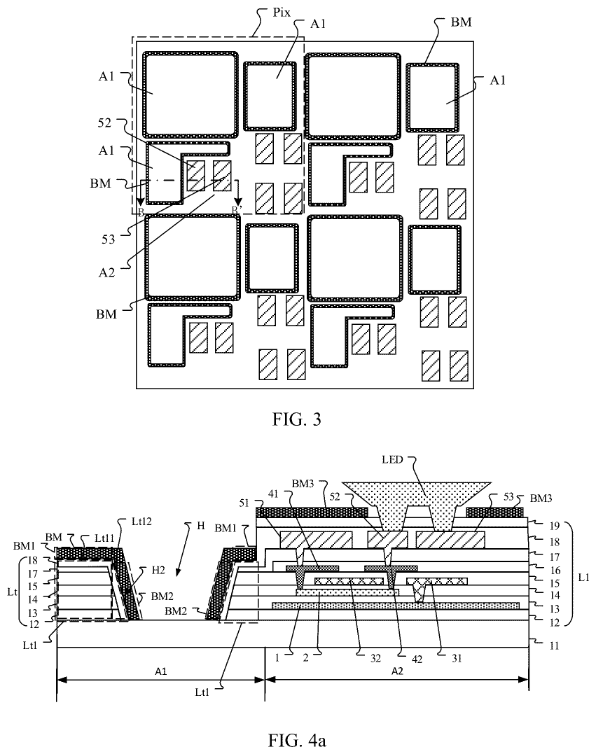

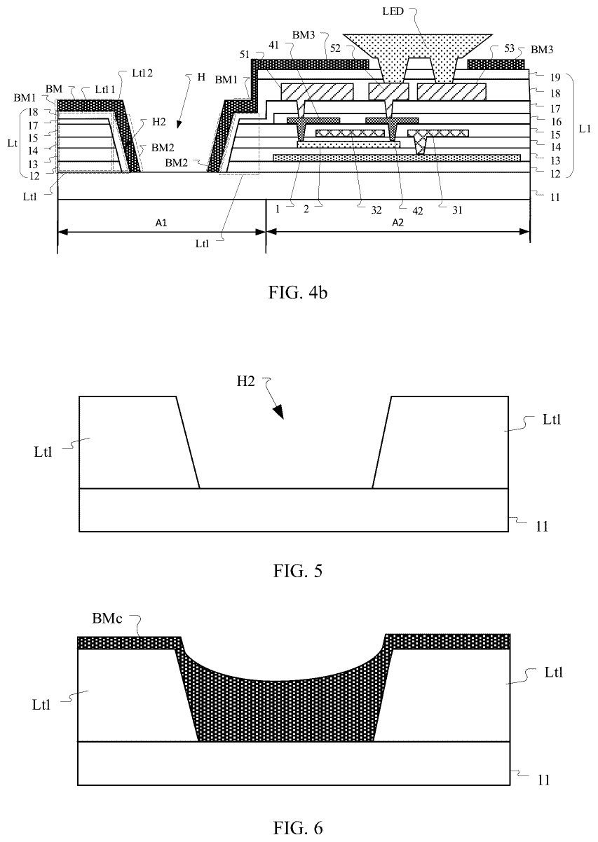

In view of the above, an embodiment of the present disclosure first provides a display panel, as shown in FIG. 3, which is a schematic diagram of a structure of the display panel in the present disclosure. The display panel includes a plurality of display units Pix, and each display unit Pix includes a transparent area A1. FIG. 4a is a sectional view of the display panel shown in FIG. 3 taken along BB′, and as shown in FIG. 4a, the display panel further includes a base substrate 11 and a composite functional layer L1. The composite functional layer L1 is provided on a side of the base substrate 11 and has a first through-hole H1 formed therein, and the first through-hole H1 is provided in the transparent area A1. The composite functional layer L1 includes a composite transparent layer Lt and a light-shielding layer BM. The composite transparent layer L1 includes a plurality of transparent functional layers, and includes a light-transmitting part Lt1 surrounding the first through-hole H1. An orthographic projection of the light-shielding layer BM on the base substrate 11 covers an orthographic projection of at least a portion of the light-transmitting part Lt1 on the base substrate 11.

In the embodiment of the present disclosure, the light-transmitting part Lt1 surrounding the first through-hole H1 is shielded by the light-shielding layer BM, the light passing through the transparent area A1 can only propagate through the first through-hole H1, and the light does not generate a phase difference between the first through-hole H1 and the light-transmitting part Lt1 during propagation, therefore such arrangement may improve the display effect of the display panel.

In an embodiment of the present disclosure, the composite functional layer L1 may include any layer arranged between the base substrate 11 and the light-emitting unit LED. For example, the composite functional layer L1 may include a first buffer layer 12, a bottom gate layer, a second buffer layer 13, an active layer, an insulating layer 14, a first gate layer, a dielectric layer 15, a first source-drain layer, a first planarization layer 16, a first passivation layer 17, a second source-drain layer, a second passivation layer 18, and a second planarization layer 19, which are stacked sequentially. The composite transparent layer Lt may include any transparent layer arranged between the base substrate 11 and the light-emitting unit LED. For example, the composite transparent layer Lt may include the first buffer layer 12, the second buffer layer 13, the insulating layer 14, the dielectric layer 15, the first planarization layer 16, the first passivation layer 17, the second passivation layer 18 and the second planarization layer 19. The first buffer layer 12, the second buffer layer 13, the insulating layer 14, the dielectric layer 15, the first planarization layer 16, the first passivation layer 17, the second passivation layer 18, and the second planarization layer 19 form the aforementioned transparent functional layer. The transparent functional layer may be understood as a functional layer with a light transmittance of more than 70%. It is to be understood that in other embodiments, other layers may also be included between the base substrate 11 and the light-emitting unit LED, and other layer stacking manners may also be possible, for example, the display panel may also include a second gate layer arranged between the first source-drain layer and the first gate layer, and a second insulating layer arranged between the second gate layer and the first source-drain layer. The light-shielding layer BM may be additionally provided on the side of the composite transparent layer Lt away from the base substrate 11, and the light-shielding layer BM may also be additionally provided between the transparent functional layers.

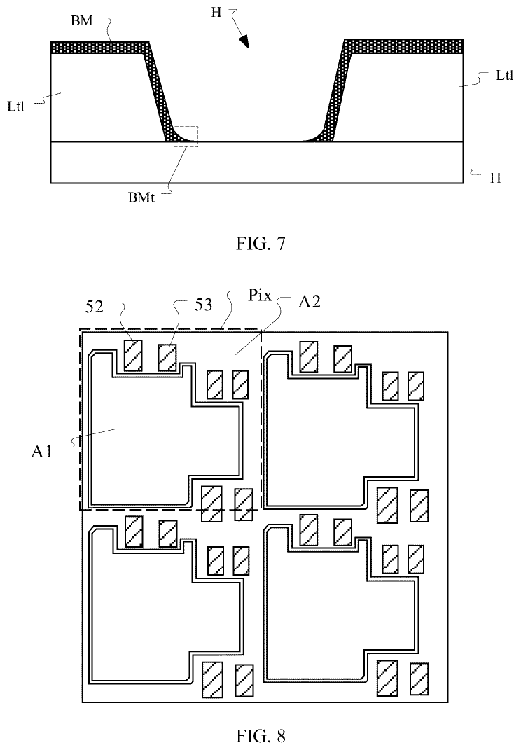

As shown in FIGS. 5-7, a flow diagram of a process for forming the light-shielding layer of the display panel in an embodiment of the present disclosure is illustrated. The light-shielding layer BM may be formed by a coating and photolithography process. As shown in FIG. 5, a second through-hole H2 may first be formed in the light-transmitting part Lt1; as shown in FIG. 6, a light-shielding material BMc may then be coated within the second through-hole H2 formed in the light-transmitting part Lt1; and as shown in FIG. 7, the light-shielding material BMc may then be etched by the photolithography process (photoresist coating, exposure, development, and etching) to form the light-shielding layer BM. When the thickness of the light-transmitting part Lt1 is relatively large, as shown in FIG. 5, the light-shielding material BMc has a large thickness in the second through-hole H2 formed in the light-transmitting part Lt1, which results in difficulty in controlling the process parameters during the exposure, and thus results in a tail BMt as shown in FIG. 7. The tail BMt may reduce the light transmittance of the display panel.

As shown in FIG. 4a, in an embodiment, the first planarization layer 16 and the second planarization layer 19 may be provided outside the area where the light-transmitting part Lt1 is located. That is, the light-transmitting part Lt1 does not include the first planarization layer 16 and the second planarization layer 19. Since the thicknesses of the first planarization layer 16 and the second planarization layer 19 are relatively large, the first planarization layer 16 and the second planarization layer 19 are provided outside the area where the light-transmitting part Lt1 is located in the embodiment, which may reduce the depth of the second through-hole H2 formed in the light-transmitting part Lt1, and thus may ameliorate the above-described tail problem. It is to be understood that in other embodiments, other transparent functional layers of the composite functional layer may also be provided outside the area where the light-transmitting part Lt1 is located.

In the embodiment, when the display panel is formed with the second through-hole H2 by an etching process, an etching duration of a portion of the second through-hole H2 close to the base substrate 11 is smaller than that of a portion of the second through-hole H2 far from the base substrate 11, and as shown in FIGS. 4a and 5, an inner diameter of the portion of the second through-hole H2 close to the base substrate 11 is smaller than that of the portion of the second through-hole H2 far from the base substrate 11.

As shown in FIG. 4a, the light-transmitting part Lt1 may include a first light-transmitting part Lt11 and a second light-transmitting part Lt12. The second through-hole H2 includes a second opening close to the base substrate 11 and a first opening far from the base substrate 11. An orthographic projection of the first light-transmitting part Lt11 on the base substrate 11 surrounds an orthographic projection of the first opening on the base substrate. An orthographic projection of the second light-transmitting part Lt12 on the base substrate 11 is located within the annulus formed by the orthographic projections of the first opening and the second opening on the base substrate, i.e. the second light-transmitting part Lt12 forms a sidewall of the second through-hole H2. The light-shielding layer may include a first light-shielding part BM1 and a second light-shielding part BM2. An orthographic projection of the first light-shielding part BM1 on the base substrate 11 covers an orthographic projection of at least a portion of the first light-transmitting part Lt11 on the base substrate 11. The second light-shielding part BM2 covers the sidewall of the second through-hole H2 to form the first through-hole H1 with the second light-shielding part BM2 as a sidewall thereof.

In an embodiment, as shown in FIGS. 4a and 5, an angle between the sidewall of the second through-hole H2 and the base substrate 11 may be greater than or equal to 70° and less than or equal to 75°, e.g., the angle between the sidewall of the second through-hole H2 and the base substrate 11 may be equal to 70°, 71°, 72°, 73°, 74°, 75° and the like. Such arrangement may facilitate the manufacturing of the light-shielding layer BM, and as the same time may ensure that the first through-hole H1 has a large light transmittance. The light-shielding layer BM may be formed by etching with trifluoromethane and argon.

In an embodiment, the material of the light-shielding layer BM may include acrylic resin and carbon black particles. It is to be understood that in other embodiments, the light-shielding layer BM may also be formed from resin and other black dyes.

In an embodiment, the display panel further includes a pixel driving circuit. As shown in FIG. 4a, the display unit further includes a pixel area A2 in which the pixel driving circuit is integrated. The light-shielding layer further includes a third light-shielding part BM3, and the third light-shielding part BM3 is provided in the pixel area A2. The third light-shielding part BM3 may shield a metal wiring in the pixel driving circuit to ameliorate the impact of the light reflection from the metal wiring on the display effect.

As shown in FIG. 4b, a schematic view of a structure of a display panel in another embodiment of the present disclosure is illustrated, in which the first light-shielding part BM1 and the third light-shielding part BM3 may be connected as a whole by a light-shielding layer provided on the sidewalls of the second passivation layer 18 and the second planarization layer 19.

It is to be understood that in other embodiments, the transparent area A1 and the pixel area A2 of the display panel may be arranged in other ways. As shown in FIG. 8, a schematic diagram of a structure of a display panel in another embodiment of the present disclosure is illustrated. In the display panel, the display unit Pix includes one transparent area A1.

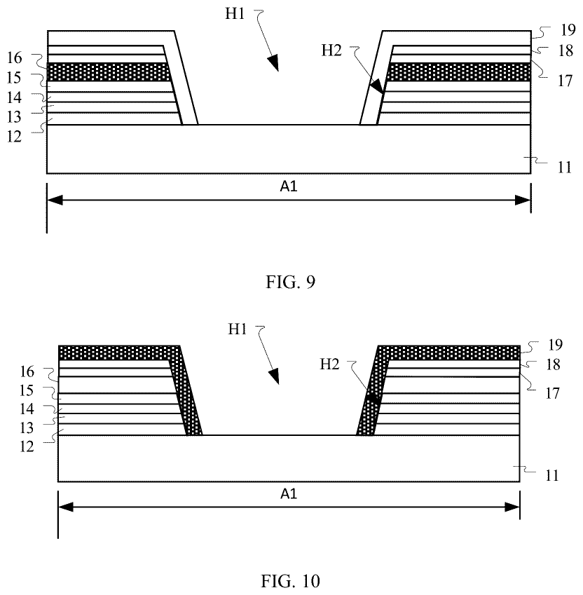

As shown in FIG. 9, a schematic diagram of a structure of a display panel in another embodiment of the present disclosure is illustrated. In the embodiment, FIG. 9 illustrates only the structure of the transparent area A1. The composite functional layer of the display panel may include a first source-drain layer (not shown), a second source-drain layer (not shown) and first planarization layer 16. The first source-drain layer is provided on a side of the base substrate, and a portion of the first source-drain layer is configured to form a data line. The second source-drain layer is provided on a side of the first source-drain layer away from the base substrate 11, and the second source-drain layer includes an electrode part for connecting to the electrode part of the light-emitting unit. The first planarization layer 16 is provided between the first source-drain layer and the second source-drain layer. The color of the first planarization layer 16 may be black, and the back first planarization layer 16 may form the light-shielding layer. In an embodiment, the first planarization layer 16 may be formed from a mixture of acetate-1-methoxy-2-acrylic acid, an acrylic polymer, and an organic dye. The first planarization layer 16 formed from the mixture of the acetate-1-methoxy-2-acrylic acid, the acrylic polymer, and the organic dye may generate gas in a heated state, thereby preventing undesirable effects such as film bursting.

As shown in FIG. 9, in an embodiment, the composite functional layer L1 may also include a first buffer layer 12, a bottom gate layer, a second buffer layer 13, an active layer, an insulating layer 14, a first gate layer, a dielectric layer 15, the first source-drain layer, the first planarization layer 16, a first passivation layer 17, the second source-drain layer, a second passivation layer 18, and a second planarization layer, which are stacked sequentially. In the manufacturing method of the display panel, after the first buffer layer 12, the second buffer layer 13, the insulating layer 14, the dielectric layer 15, the first planarization layer 16, the first passivation layer 17, and the second passivation layer 18 are formed, a second through-hole H2 may be formed by an etching process, and the second planarization layer 19 may then be formed over the second through-hole H2 to form a first through-hole H1 with a sidewall thereof formed by the second planarization layer 19.

In an embodiment, since a distance between the first planarization layer 16 and the base substrate is relatively small, a black residual tail due to a large level difference shown in FIG. 7 is not formed when the first planarization layer 16 is formed. In other embodiments, in the manufacturing method of the display panel, a through-hole may be formed before the formation of the first planarization layer 16, and then, the first planarization layer is formed within the through-hole, so that the first planarization layer may cover the sidewall of the through-hole.

As shown in FIG. 10, a schematic diagram of a structure of a display panel in another embodiment of the present disclosure is illustrated. In an embodiment, FIG. 10 shows only a structure of the transparent area A1. In an embodiment, the display panel further includes a light-emitting unit, and the composite functional layer further includes a second source-drain layer (not shown) and a second planarization layer 19. The second source-drain layer is provided on a side of the base substrate 11, and the second source-drain layer includes an electrode part for connecting to the light-emitting unit. The second planarization layer 19 is provided on the side of the second source-drain layer away from the base substrate. The color of the second planarization layer 19 is black, and the black second planarization layer 19 may form the light-shielding layer. In an embodiment, the second planarization layer 19 may also be formed from a mixture of acetate-1-methoxy-2-acrylic acid, acrylic polymer, and organic dye.

As shown in FIG. 10, in an embodiment, the composite functional layer L1 may also include a first buffer layer 12, a bottom gate layer, a second buffer layer 13, an active layer, an insulating layer 14, a first gate layer, a dielectric layer 15, a first source-drain layer, a first planarization layer 16, a first passivation layer 17, the second source-drain layer, a second passivation layer 18, and the second planarization layer 19, which are provided sequentially. In the manufacturing method of the display panel, after the first buffer layer 12, the second buffer layer 13, the insulating layer 14, the dielectric layer 15, the first planarization layer 16, the first passivation layer 17, and the second passivation layer 18 are formed, a second through-hole H2 may be formed by an etching process, and the second planarization layer 19 may then be formed on the second through-hole H2 to form a first through-hole H1 with a sidewall thereof formed by the second planarization layer 19.

In the embodiment, since a distance between the second planarization layer 19 and the base substrate is relatively small, a black residual tail due to a large level difference shown in FIG. 7 is not formed when the second planarization layer 19 is formed.

In an embodiment, the light-shielding layer may be any light-shielding layer in the composite functional layer L1. The light-shielding layer may be a film layer additionally provided in the display panel or a functional film layer of the display panel itself, for example, the light-shielding layer may include one or more layers of the buffer layer, the insulating layer, the passivation layer, the planarization layer, and the conductive layer in the composite functional layer L1.

In an embodiment, the display panel may be a Mini LED display panel or a Micro LED display panel. That is, in an embodiment, the light-emitting unit may be a micro light-emitting diode (Micro LED), and a mini light-emitting diode (Mini LED). The size of the Mini LED is about 100-300 μm, and the size of the Micro LED is 100 μm or less. It is to be understood that in other embodiments, the light-emitting unit may also be a light-emitting unit such as an LED and an OLED.

An embodiment also provides a display device including the display panel described above. The display device may be applied in fields such as commercial advertisements, transparent windows, car windows, and VR glasses.

A person skilled in the art may easily conceive of other embodiments of the present disclosure upon consideration of the specification and practice of the invention disclosed herein. This application is intended to cover any variations, uses, or adaptations of the present disclosure that follow the general principles of the present disclosure and include the common knowledge and the customary technical means in the art not disclosed herein. The specification and embodiments are to be regarded as exemplary only, and the true scope and spirit of the present disclosure are indicated by the appended claims.

It is to be understood that the present disclosure is not limited to the precise structure which has been described above and illustrated in the accompanying drawings, and that various modifications and alterations may be made without departing from the scope thereof. The scope of the present disclosure is limited only by the appended claims.

What is claimed is:

1. A display panel comprising a plurality of display units, each of the plurality of display units comprising a transparent area, and the display panel further comprising:
a base substrate; and
a composite functional layer, provided on a side of the base substrate and having a first through-hole formed therein, the first through-hole being provided in the transparent area,
wherein the composite functional layer comprises:
a composite transparent layer, comprising a plurality of transparent functional layers, and comprising a light-transmitting part surrounding the first through-hole; and
a light-shielding layer, an orthographic projection of the light-shielding layer on the base substrate covering an orthographic projection of at least a portion of the light-transmitting part on the base substrate.

2. The display panel according to claim 1, wherein the display panel further comprises a light-emitting unit, and the composite functional layer further comprises:
a second source-drain layer, provided on the side of the base substrate, and comprising and electrode part connecting to the light-emitting unit; and
a second planarization layer, provided on a side of the second source-drain layer away from the base substrate,
wherein the light-shielding layer is provided on a side of the second planarization layer away from the base substrate.

3. The display panel according to claim 1, wherein the display panel further comprises a light-emitting unit, and the composite functional layer further comprises:
a first source-drain layer, provided on the side of the base substrate, a portion of the first source-drain layer being configured to form a data line;
a second source-drain layer, provided on a side of the first source-drain layer away from the base substrate, and comprising an electrode part connecting to the light-emitting unit; and
a first planarization layer, provided between the first source-drain layer and the second source-drain layer, a color of the first planarization layer being black and the first planarization layer forming the light-shielding layer.

4. The display panel according to claim 1, wherein the display panel further comprises a light-emitting unit, and the composite functional layer further comprises:
a second source-drain layer, provided on the side of the base substrate, and comprising an electrode part connecting to the light-emitting unit; and
a second planarization layer, provided on a side of the second source-drain layer away from the base substrate, a color of the second planarization layer being black, and the second planarization layer forming the light-shielding layer.

5. The display panel according to claim 1, wherein the display panel further comprises a light-emitting unit, and the composite functional layer comprises any film layers provided between the light-emitting unit and the base substrate;
the composite transparent layer comprises any film layers provided between the light-emitting unit and the base substrate; and
the light-shielding layer comprises at least one of a buffer layer, an insulating layer, a passivation layer, a planarization layer, and a conductive layer provided between the light-emitting unit and the base substrate.

6. The display panel according to claim 1, wherein the light-shielding layer is provided on a side of the composite transparent layer away from the base substrate, and at least a portion of a sidewall of the first through-hole is formed by the light-shielding layer; or
the light-shielding layer is provided between the transparent functional layers, and the sidewall of the first through-hole is formed by the transparent functional layer.

7. The display panel according to claim 1, wherein the light-shielding layer is provided on a side of the composite transparent layer away from the base substrate, a second through-hole is formed in the composite transparent layer, the first through-hole is provided in the second through-hole, and the light-shielding layer covers a sidewall of the second through-hole to form the first through-hole; and
wherein an inner diameter of the second through-hole at a location close to the base substrate is smaller than an inner diameter of the second through-hole at a location far from the base substrate.

8. The display panel according to claim 7, wherein an angle between the sidewall of the second through-hole and the base substrate is greater than or equal to 70° and less than or equal to 75°.

9. The display panel according to claim 7, wherein the second through-hole comprises a first opening far from the base substrate, and the light-transmitting part comprises a first light-transmitting part;
an orthographic projection of the first light-transmitting part on the base substrate surrounds an orthographic projection of the first opening on the base substrate; and
the light-shielding layer comprises a first light-shielding part, and an orthographic projection of the first light-shielding part on the base substrate covers an orthographic projection of at least a portion of the first light-transmitting part on the base substrate.

10. The display panel according to claim 2, wherein the composite functional layer further comprises:
a first source-drain layer, provided between the base substrate and the second source-drain layer, a portion of the first source-drain layer being configured to form a data line; and
a first planarization layer, provided between the first source-drain layer and the second source-drain layer,
wherein the first planarization layer and the second planarization layer are provided in an area outside the light-transmitting part.

11. The display panel according to claim 2, wherein the display panel further comprises a pixel driving circuit, and the display unit further comprises a pixel area integrated with the pixel driving circuit; and
the light-shielding layer further comprises a third light-shielding part, and the third light-shielding part is provided in the pixel area.

12. The display panel according to claim 2, wherein a material of the light-shielding layer comprises acrylic resin and carbon black particles.

13. The display panel according to claim 3, wherein the light-shielding layer is formed of a mixture of acetate-1-methoxy-2-acrylic acid, acrylic polymer, and organic dye.

14. The display panel according to claim 1, wherein the display panel is a Mini LED display panel or a Micro LED display panel.

15. A display device comprising a display panel, wherein the display panel comprises a plurality of display units, each of the plurality of display units comprises a transparent area, and the display panel further comprises:
a base substrate; and
a composite functional layer, provided on a side of the base substrate and having a first through-hole formed therein, the first through-hole being provided in the transparent area,
wherein the composite functional layer comprises:
a composite transparent layer, comprising a plurality of transparent functional layers, and comprising a light-transmitting part surrounding the first through-hole; and
a light-shielding layer, an orthographic projection of the light-shielding layer on the base substrate covering an orthographic projection of at least a portion of the light-transmitting part on the base substrate.

16. The display device according to claim 15, wherein the display panel further comprises a light-emitting unit, and the composite functional layer further comprises:
a second source-drain layer, provided on the side of the base substrate, and comprising and electrode part connecting to the light-emitting unit; and
a second planarization layer, provided on a side of the second source-drain layer away from the base substrate,
wherein the light-shielding layer is provided on a side of the second planarization layer away from the base substrate.

17. The display device according to claim 15, wherein the display panel further comprises a light-emitting unit, and the composite functional layer further comprises:
a first source-drain layer, provided on the side of the base substrate, a portion of the first source-drain layer being configured to form a data line;
a second source-drain layer, provided on a side of the first source-drain layer away from the base substrate, and comprising an electrode part connecting to the light-emitting unit; and
a first planarization layer, provided between the first source-drain layer and the second source-drain layer, a color of the first planarization layer being black and the first planarization layer forming the light-shielding layer.

18. The display device according to claim 15, wherein the display panel further comprises a light-emitting unit, and the composite functional layer further comprises:
a second source-drain layer, provided on the side of the base substrate, and comprising an electrode part connecting to the light-emitting unit; and
a second planarization layer, provided on a side of the second source-drain layer away from the base substrate, a color of the second planarization layer being black, and the second planarization layer forming the light-shielding layer.

19. The display device according to claim 15, wherein the display panel further comprises a light-emitting unit, and the composite functional layer comprises any film layers provided between the light-emitting unit and the base substrate;
the composite transparent layer comprises any film layers provided between the light-emitting unit and the base substrate; and
the light-shielding layer comprises at least one of a buffer layer, an insulating layer, a passivation layer, a planarization layer, and a conductive layer provided between the light-emitting unit and the base substrate.

20. The display device according to claim 15, wherein the light-shielding layer is provided on a side of the composite transparent layer away from the base substrate, and at least a portion of a sidewall of the first through-hole is formed by the light-shielding layer; or
the light-shielding layer is provided between the transparent functional layers, and the sidewall of the first through-hole is formed by the transparent functional layer.
